(19) United States
(12) Patent Application Publication
(10) Pub. No.: US 2011/0109200 A1
(43) Pub. Date: May 12, 2011

(54) TWO- OR MULTI-LAYER FERRELECTRET AND METHOD FOR THE PRODUCTION THEREOF

(75) Inventors: Werner JENNINGER, Koln (DE); Joachim WAGNER, Koln (DE); Carsten BENECKE, Weil am Rhein (DE)

(73) Assignee: Bayer MaterialScience AG, Leverkusen (DE)

(21) Appl. No.: 12/941,291

(22) Filed: Nov. 8, 2010

(30) Foreign Application Priority Data
Nov. 12, 2009 (EP) EP 09014141.7

(51) Int. Cl. H01L 41/04; H01L 41/113; H01L 41/26

(52) U.S. Cl. 310/338; 310/367; 29/25.35

(57) ABSTRACT

The present invention relates to a method for producing two- or multi-layer ferroelectrets with defined voids, with the exception of three-layer ferroelectrets with a perforated middle layer made of PTFE between two FEP layers, involving, introducing one or more clearances into at least one surface side of a polymer film element by means of a method of removal, applying a first covering to the surface side of the polymer film element comprising clearances formed in step A), and joining the polymer film element and the covering to form a polymer film composite, the clearances being closed while voids are formed, and to a two- or multi-layer ferroelectret, with the exception of three-layer ferroelectrets with a perforated middle layer made of PTFE between two FFP layers, in particular produced by this method. The invention also relates to a piezoelectric element containing a ferroelectret multi-layer composite according to the invention.

### FIELD OF THE INVENTION

The present invention relates to a method for producing two- or multi-layer ferroelectrets, with the exception of three-layer ferroelectrets with a perforated middle layer made of PTFE between two HP layers, with voids and to two- and multi-layer ferroelectrets produced by this method.

### BACKGROUND OF THE INVENTION

Piezoelectric materials are capable of converting a mechanical pressure linearly into an electrical voltage signal. Conversely, an electric field applied to the piezoelectric material can be transformed into a change in the geometry of the transducer. Piezoelectric materials are already integrated as active components in many applications. These include, for example, structured pressure sensors for keyboards or touchpads, acceleration sensors, microphones, loudspeakers, ultrasonic transducers for applications in medical engineering, marine technology or materials testing. In WO 2006/053528 A1, for example, a description is given of an electroacoustic transducer based on a piezoelectric element containing polymer films.

In recent years, a new class of piezoelectric polymers, known as ferroclectrets, have been increasingly the focus of research. The ferroelectrets are also known as piezoelectrets. Ferroelectrets are polymer materials with a voids structure which can store electric charges over long periods of time. Previously known ferroelectrets have, for example, a cellular void structure and are formed either as foamed polymer films or as multi-layer systems comprising polymer films or polymer weaves. If electric charges are distributed on the various surfaces of the voids in accordance with their polarity, each charged void represents an electric dipole. If the voids are then deformed, this causes a change in the size of the dipole and leads to a current flow between external electrodes. The ferroelectrets may exhibit piezoelectric activity that is comparable to that of other piezoelectrics.

In U.S. Pat. No. 4,654,546, a description is given of a method for producing polypropylene foam films as a precursor for a ferroelectret film. In that method, filler particles are added to the polymer films. Titanium dioxide is used, for example, as the filler. After extrusion, the polypropylene films are biaxially stretched, so that small voids form in the film around the filler particles. This method has also been applied to other polymers. For example, the production of ferroelectret films from cyclo-olefin copolymers (COC) and cyclo-olefin polymers (COP) is described in Eetta Saarimäki, Mika Paajanen, Ann-Mari Savijärvi, and Hannu Minkkinen, Michael Wegener, Olena Voronina, Robert Schulze, Werner Wirges and Reimund Gerhard-Multhaupt “Novel Heat Durable Electromechanical Film: Processing for Electromechanical and Electret Applications”, IEEE Transactions on Dielectrics and Electrical Insulation 13, 963-972 (October 2006). The foamed polymer films have the disadvantage that a wide bubble size distribution may be obtained. As a result, not all of the bubbles can be charged uniformly well during the subsequent charging step.

Multi-layer systems comprising closed outer layers and a porous or perforated middle layer have been described in several publications in recent years. These include the article by Z. Hu and H. von Seggern, “Air-breakdown charging mechanism of fibrous polytetrafluoroethylene films”, Journal of Applied Physics, Vol. 98, paper 014108, 2005 and “Breakdown-induced polarization buildup in porous fluoropolymer sandwiches: A thermally stable piezoelectret”, Journal of Applied Physics, Vol. 99, paper 024102, 2006, as well as the publication by H. C. Basso, R. A. P. Altafilm, R. A. C. Altafilm, A. Mellinger, Peng Fang, W. Wirges and R. Gerhard “Three-layer ferroelectrets from perforated Teflon-PTFE films fused between two homogeneous Teflon-FEP films” IEEE, 2007 Annual Report Conference on Electrical Insulation and Dielectric Phenomena, 1-4244-1482-2/07, 453-456 (2007) and the article by Jinfeng Huang, Xiaoqing Zhang, Zhongfu Xia and Xuewen Wang “Piezoelectrets from laminated sandwiches of porous polytetrafluoroethylene films and nonporous fluoroethylenepropylene films” Journal of Applied Physics, Vol. 103, paper 084111, 2008. The layer systems with a porous or perforated middle layer often have greater piezo constants than the systems described above.

A structuring of the polymer layers by pressing a metal grid onto a stack of polymer layers comprising at least three FEP and PTFE layers piled one above the other in alternating sequence is described in the publications by X. Zhang, J. Hillenbrand and G. M. Sessler, “Thermally stable fluorocarbon ferroelectrets with high piezoelectric coefficient”, Applied Physics A, Vol. 84, pp. 139-142. 2006 and “Ferroelectrets with improved thermal stability made from fused fluorocarbon layers”, Journal of Applied Physics, Vol. 101, paper 054114, 2007, as well as in Xiaoqing Zhang, Jinfeng Huang and Zhongfu Xia “Piezoelectric activity and thermal stability of cellular fluorocarbon films” PHYSIC′A SCRIPTA Vol. T129 pp. 274-277, 2007. The pressing together of the layers by the grid at a temperature that lies above the melting point of FEP and below that of PTFE has the effect that the polymer layers are joined to one another in accordance with the grid structure in such a way that dome-shaped or bubble-shaped voids with a rectangular base area form between the bars of the grid. However, this method leads to ferroelectrets of varying quality, since the formation of uniform voids can only be controlled with difficulty, in particular as the number of layers increases.

Another method for producing bubble-shaped voids using a grid has been described by R. A. C. Altafim, H. C. Basso, R. A. P. Altafim, L. Lima, C. V. De Aquino, L. Gonalves Neto and R. Gerhard-Multhaupt in “Piezoelectrets from thermo-formed bubble structures of fluoropolymer-electret films”, IEEE Transactions on Dielectrics and Electrical Insulation, Vol. 13, No. 5, pp. 979-985, 2006. In that method, two TEFLON-FE? films arranged one above the other are arranged between a metal grid and an upper cylindrical metal part. This construction is pressed with the metal grid onto a lower cylindrical metal part which has openings for applying a vacuum. The FEP films are heated through the upper metal part and the lower film is drawn into the openings in the grid and corresponding voids are formed by a vacuum applied to the lower metal part. The described methods using a grid for forming voids in the polymer multi-layer composites are complex and difficult to transfer to a large scale.

An advantageously simple production method for ferroelectrets with tubular voids of homogeneous size and structure has been described by R. A. P. Altafim, X. Qiu, W. Wirges, R. Gerhard, R. A. C. Ahem, H. C. Basso, W. Jenninger and J. Wagner in the article “Template-based fluoroethylenepropylene piezoelectrets with tubular channels for transducer applications”, Journal of Applied Physics, 106, 014106, 2009. In the method described therein, firstly a sandwich arrangement of two FEP films and a PTFE mask film placed in between is prepared. The PTFE film was structured by laser ablation beforehand. The film stack formed is laminated, the FEP films are joined to one another and the mask film is subsequently removed, i.e. pulled out, to expose the voids. The FEP films are therefore produced by stamping, i.e. the structure of the FEP films is formed as an impression by the PTFE film that is removed later. In this case, there is no removal of material of the FEP films. A disadvantage of this method is that the PTFE film may tear or even tear off when it is pulled out. This makes it more difficult or even impossible to remove the PTFE film completely. If the PTFE film remains in the FEP film laminate, use of the laminate as a ferroelectret is possible only to a restricted extent or not at all. Furthermore, with this method the FEP films can only be structured to a very restricted extent, since it must be possible to pull out the PTFE film after the stamping. Only open and/or long structures can be stamped. The stamping of area-optimized closed structures is not possible with this method. Gerhard et al. (2007 Annual Report Conference on Electrical Insulation and Dielectric Phenomena, pages 453 to 456) describes in the article “Three-layer ferroelectrets form perforated Teflon®-PTFE films fused between two homogeneous Teflon®-FEP films” the production of a three-layer ferroelectret in which a polytetrafluoroethylene film that has been provided with a multiplicity of uniform clearances right through by mechanical or laser-based drilling is arranged between two uniform fluoroethylene propylene films. However, with this method it is only possible to produce fcrroelectrets that have three or more layers. The production of ferroelectrets with only two layers, which in comparison with the three-layer ferroelectrets can be produced more simply and inexpensively without loss of quality, is not disclosed and is also not possible with this method. Moreover, only the production of three-layer ferroelectrets with a perforated middle layer, i.e. provided with clearances completely through, made of PTFE between two FEP layers is disclosed, but not the production of three-layer ferroelectrets of other materials. This represents a restriction in the choice of materials, in particular since PTFE and FEP are expensive in comparison with other polymers. Furthermore, it is generally disfavored to use fluorinated materials, since they are problematic in disposal and, in the case of incineration, form toxic products. The production of ferroelectrets with four, five or more layers is also not disclosed. However, such ferroelectrets offer many possibilities for the configuration of the voids, since the clearances of the individual layers can be configured differently.

WO2009/018130 discloses the production of a piezoelectric layered structure with ceramic structured elements. The production of these structures is very laborious, since they either have to be worked from solid ceramic or provided by means of casting, molding and burning methods. Both methods are very time-consuming and energy-intensive.

Ferroelectrets are also of increasing interest for commercial applications, for example for sensor, actuator and generator systems. Applicability of a production method on an industrial scale is desirable for cost-effectiveness.

### SUMMARY OF THE INVENTION

The invention therefore overcomes the disadvantages inherent in the art by providing an alternative method for producing two- or multi-layer ferroelectrets, with the exception of three-layer ferroelectrets with a perforated middle layer made of PTFE between two FEP layers, with which defined ferroelectret void structures can be created and which can be carried out simply and at low cost even on a large, industrial scale.

These and other advantages and benefits of the present invention will be apparent from the Detailed Description of the Invention herein below.

### BRIEF DESCRIPTION OF THE FIGURES

The present invention will now be described for purposes of illustration and not limitation in conjunction with the figures, wherein:

FIG. 1 schematically shows the forming of a ferroelectret two-layer composite according to the invention,

FIG. 2 schematically shows the forming of a two-layer composite according to the invention with a covering with clearances,

FIG. 3a shows a schematic cross-sectional representation of a polymer film element according to the invention comprising two joined polymer films,

FIG. 3b shows a schematic cross-sectional representation of a three-layer composite according to the invention comprising the polymer film element 1 shown in FIG. 3a and a continuous covering 2,

FIG. 3c shows a schematic cross-sectional view of the ferroelectret three-layer composite shown in FIG. 3b after the charging process and after the attachment of electrodes 6a and 6b,

FIG. 4 shows a schematic cross section through the electromechanical transducer according to the invention with three ferroelectret multi-layer arrangements according to the invention stacked one above the other, and

FIGS. 5a to 5e show various forms possible according to the invention of clearances in a polymer film element and/or a covering, in each case in a plan view.

### DETAILED DESCRIPTION OF THE INVENTION

The present invention will now be described for purposes of illustration and not limitation. Except in the operating examples, or where otherwise indicated, all numbers expressing quantities, percentages, and so forth in the specification are to be understood as being, modified in all instances by the term “about.”

According to the invention, a method for producing a two- or multi-layer ferroelectret with voids, with the exception of a three-layer ferroelectret with a perforated middle layer made of PTFE between two FEP layers, involving the following steps:
A) introducing one or more clearances into at least one surface side of a polymer film element by means of a method of removal, ,
B) applying a first covering to the surface side of the polymer film element having clearances formed in step A), and
C) joining the polymer film element and the first covering to form a two- or multi-layer ferroelectret, the clearances being closed while voids are formed.

The voids may be referred to as defined, since they have a predetermined structure.

A “covering” is understood according to the invention as meaning a polymer film or a polymer film composite with which the clearance or the clearances in the first surface of the first polymer film are closed while voids are formed and at the same time an outwardly directed continuous surface without clearances forms on the other surface side in the two- or multi-layer ferroelectret created.

For the purposes of the present invention, “according to the invention” in conjunction with “two- and multi-layer ferroelectrets” always means two- or multi-layer ferroelectrets, with the exception of three-layer ferroelectrets with a perforated middle layer made of PTFE between two FEP layers.

“Multi-layer ferroelectrets” as used herein means that the ferroelectret has three, four, five, six, seven, eight, nine or more layers (polymer film elements), preferably one, two, three, four, five, six, seven, eight layers that have clearances. In particular, ferroelectrets with two, three, four, five and more layers that have clearances offer many possibilities for the configuration of the voids, since the clearances of the individual layers can be configured differently. The clearances may or may not perforate the layer. If the clearances of two layers are facing one another, it may be advisable to introduce an non-perforated layer between these layers, it being possible for this layer not to have any clearances or to have clearances only on one side or to have clearances on both sides.

Two-layer ferroelectrets, in comparison, offer the advantage of simple and low-cost production, it being possible for two-layer ferroelectrets to have both one layer and two layers that have removals.

The two-layer ferroelectret produced according to the invention contains, in other words, voids formed between two polymer films. The surfaces directed towards one another of the polymer film element and of the covering are, in this embodiment, joined to one another between the voids. According to the invention, the form and dimensioning of the voids can be advantageously produced in a very exactly predetermined and defined manner. The removal of polymer material in step A), and consequently the formation of clearances in at least one surface at least of the polymer film element, is important in the method according to the invention for the formation of the defined voids in the two- or multi-layer ferroelectret according to the invention created.

The clearances may be advantageously formed in numerous different forms by the method according to the invention. The form of the clearances is not restricted to a cylindrical form with a circular cross-sectional area. In addition, the method according to the invention offers the possibility of combining clearances formed in various forms. In this way, the overall void volume of the resultant voids can be advantageously maximized. On the other hand, the electromechanical, in particular piezoelectric, properties of the two- or multi-layer ferroelectrets and electromechanical transducers produced by the method according to the invention can be adapted by choosing the form of the clearances, their arrangement and/or distribution.

In the simplest case, the covering may, according to the invention, be a continuous polymer film entirely without clearances and the polymer film element may be a polymer film. If the covering is then applied to the first surface side of the polymer film, comprising clearances, a two-layer ferroelectret with voids according to the invention can be created.

In principle, the polymer films used for the polymer film element and the covering may be produced from any plastics material that allows clearances to be introduced by methods of removal, the polymer films to be joined and voids to be formed and, furthermore, is suitable for making a polarization process possible in the voids and for separating the charge layers formed after the charging process in the polymer films.

The polymer films used for the two- or multi-layer ferroelectret according to the invention may, according to the invention, be the same or different polymer materials, for example selected from the group of polycarbonates, perfluorinated or partly fluorinated polymers and copolymers such as PTFE, fluoroethylene propylene (FEP), perfluoroalkoxy ethylene (PFA), polyesters such as polyethylene terephthalate (PET) or polyethylene naphthalate (PEN), cyclo-olefin polymers, cyclo-olefin copolymers, polyimides, in particular polyether imide, polyethers, polymethyl methacrylate and polypropylene or polymer blends. With these materials, good to very good piezo activities can be achieved. The wide selection of materials according to the invention can advantageously also make adaptation to specific applications possible. However, it is not according to the invention to use a perforated middle layer made of PTFE between two FEP layers in the case of a three-layer ferroelectret, since PTFE and FEP are expensive in comparison with other polymers. Furthermore, it is generally preferred not to use fluorinated materials, since they are problematic in disposal and, in the case of incineration, form toxic products.

The polymer films may in each case have with preference a thickness of from preferably ≧10 μm to ≦500 μm, more preferably from 15 μm to 300 μm. The thickness of the various polymer films, in other words their layer thickness, in a two- or multi-layer ferroelectret according to the invention may in this case be chosen to be the same or different. A particularly suitable thickness of the polymer films may be advantageously selected in each case in dependence on the polymer material and with regard to the desired application. What really matters is that the voids formed in step C) of the method do not collapse. Thus, stiffer materials may be made thinner than comparatively more elastic polymer materials.

The polymer films may be configured as film sheets or, in particular with regard to large-scale production, advantageously also as film webs, which can in step B) be arranged one above the other and in step C) be joined to one another while the cavities are formed. The film sheets may in this case have a rectangular, regular or irregular polyhedral form or a round, for example circular, elliptical or oval base area, the films arranged one above the other expediently having the same base area, at least in the region arranged one above the other. In principle, the base area may also be adapted to a specific application.

In an optional step D) according to the invention, it is advantageously possible to resort to known, established methods for the electrical charging and polarization of the inner surfaces of the voids with opposed electric charges. Polarization of the opposite sides of the voids may be realized for example by a corona discharge or by plasma processes. A corona treatment may advantageously also be used as well on a large scale.

The removal and formation of clearances in a polymer film carried out in step A) and the joining to at least one covering in step B) allow exactly predetermined voids to be created and produced in a defined manner by the method provided. A further advantage is therefore that, with the procedure according to the invention, different resonant frequencies, such as occur in an uncontrolled manner in the case of foamed ferroelectric films as a result of nonuniform bubbles, can be avoided. By contrast with this, it is even possible according to the invention to create differently configured voids, and consequently set different properties, for example piezo activities, in partial regions of the polymer film composite created.

In one embodiment of the inventive method, the removal, and consequently the introduction of clearances into the at least one surface of the first polymer film, in step A) may be performed by laser ablation or etching. With equal preference, methods of removal such as planing, milling or grinding may be used for forming the clearances. With the aforementioned methods of forming the clearances, both the form and the dimensioning of the voids then formed in the next step B) by applying the covering are advantageously almost freely selectable, and can be adapted to the desired mechanical and electrical requirements of the respective application in dependence on the film materials and their properties and the respective film thickness. The invention likewise may include introducing the same clearances, if appropriate, into a polymer film by means of different methods of removal.

In another embodiment of the inventive method, one or more clearances may likewise be introduced into a surface side of the covering in a step A1). The introduction of the clearances may equally be performed here, for example, by laser ablation, etching, planing, milling and/or grinding. The application of the covering to the first surface side, with clearances, of the polymer film element may, for example, be performed according to the invention in such a way that the clearances in the surface sides of the polymer film element and the covering that are directed towards one another entirely or partially overlap, so that the clearances can form at least one common void. For example, the surface sides with the clearances of the polymer film element and the covering may in this case be of a congruent configuration. The clearances in the surface sides of the polymer film element and the covering may, however, also be arranged specifically such that they do not overlap, so that in this case two layers of voids can be created by the joining of the polymer film element and the covering. The voids of the two layers are in this case arranged offset in relation to one another.

The polymer films used in the polymer film element and the covering may, for example, have a thickness of from ≧10 μm to ≦800 μm and the clearances formed may have a depth of from ≧10 μm to ≦500 μm, as well as a width of from ≧10 μm to ≦5000 μm. A height of from ≧10 μm≦250 μm and a width of from ≧50 μm to ≦3000 μm is preferred for the voids. More preferably, the voids have a width of from ≧100 μm to ≦2000 μm. The combination of the film properties and the form and dimensioning of the voids formed may preferably be chosen such that the film portions are kept at a distance to not touch in any situation encountered during use. The methods of removal mentioned also have the advantage that they can be automated and, if appropriate, may be carried out as a continuous process.

In a two- or multi-layer ferroelectret produced according to the invention, given a polymer film thickness of from 10 μm to 500 μm, the voids may, preferably, have a height of from ≧10 μm to ≦500 μm. The height refers in particular to the height of the voids in cross section. More preferably, the voids may have a height of from ≧10 μm to ≦250 μm.

The voids may be formed in numerous different forms by the method according to the invention. The form of the voids is therefore not restricted to a bubble-shaped. cylindrical, tubular or channel-like form with a circular or rectangular cross-sectional area perpendicularly to the run of the layers of the polymer films. In addition, the method according to the invention offers the possibility of combining voids formed in various forms. In this way, the overall void volume of the resultant voids can be advantageously maximized. On the other hand, the electromechanical, in particular piezoelectric, properties of the two- or multi-layer ferroelectrets and electromechanical transducers produced by the method according to the invention can be adapted by choosing the form, size and shape of the voids, their number, arrangement and/or distribution.

The voids may be formed in forms with a rather small areal extent, such as lines, for example bent or straight, single or crossed lines, or peripheral lines of geometric figures, for instance a circular line or a peripheral line of a cross, or structures with a larger area, such as rectangles, circles, crosses, et cetera. The form and dimensioning of the voids is preferably set such that the polymer films cannot touch perpendicularly to their layer run within the void and/or the overall void volume resulting after completion is as great as possible. In other words, it is intended in particular that the positive and negative charges applied by polarization to the inner surfaces of the voids cannot touch.

The voids may be formed in shapes which have a cross-sectional area parallel to the layer run of the polymerfilms selected from substantially round, for example circular, elliptical or oval, polygonal, for example triangular, rectangular, trapezoidal, rhomboidal, pentagonal, hexagonal, in particular honeycomb-shaped, cruciform, star-shaped and partially round and partially polygonal, for example S-shaped, cross-sectional areas. If the two- or multi-layer ferroelectrets according to the invention are stacked in a number of layers, that is to say form stacks, the voids in the individual two- or multi-layer ferroelectrets according to the invention may be of the same or different configurations in comparison with other two- or multi-layer ferroelectrets according to the invention of the respective stack. This comprises not only their form, size and shape but also the number of voids, their arrangement and/or distribution.

The voids within the two- or multi-layer ferroelectret according to the invention formed may advantageously make the two- or multi-layer ferroelectret according to the invention that is to be produced softer along its thickness, to lower its modulus of elasticity and make a polarization process possible in the resultant voids.

Within the scope of the method according to the invention, the voids in the two- or multi-layer ferroelectret formed may be formed not only in a homogeneously distributed manner but also in a heterogeneously distributed manner. In particular, it may also be advantageous depending on the application area of a two- or multi-layer ferroelectret according to the invention to be produced or of a stack of a plurality thereof for the voids to be formed in a specific, locally resolved heterogeneosly distributed manner.

In another embodiment of the method according to the invention, the polymer film element and/or the covering contains at least a first and a second polymer film joined to one another, it being possible in particular for the introduction of the clearances into the surface side of the polymer film element in step A) and/or the introduction of the clearances into the surface side of the covering in step A1) to be performed through as far as the second polymer film. In other words, the clearances may be introduced through as far as the bounding surface of the next joined polymer film by removal of the polymer material. In this way, the heights of the voids can be advantageously set even more exactly, and consequently particularly uniform voids can be created in a simple way.

The joining of the polymer films to form a two- or multi-layer ferroelectret according to the invention in step C) may, for example, be performed according to the invention preferably by laminating, adhesive bonding, clasping, clamping, screwing, riveting or welding, in particular by laser welding, ultrasonic welding or vibration welding.

The joining of the polymer films by laminating may be carried out thermally, under increased pressure and/or by means of ultrasound and/or by means of irradiation with ultraviolet light or infrared light. As a result, the material selection for the polymer films can be advantageously increased further. The conditions for the lamination are in this case expediently chosen such that the film layers join, but at the same time the structuring of the polymer film element provided by the clearances is preserved to the greatest extent, and thus a dimensional stability and defined formation of the voids is ensured. Before the lamination, the material of the structured polymer film element and/or the material of the covering may be completely solidified, for example completely dried and/or completely crosslinked, and/or completely hardened and/or completely crystallized. As a result, the dimensional stability of the two- or multi-layer ferroelectret according to the invention containing voids created according to the inventive method can be improved.

In a further refinement, the polymer films may, in addition to the lamination, also be joined to one another by an adhesive bond. This adhesive bond may be produced, for example, by means of acrylate adhesive. As a result, the mechanical joining of the polymer films can be assisted and improved.

The joining of the polymer films in step C) by means of an adhesive bond may be performed, for example, with acrylate adhesive. Alternatively, it is also possible, when joining polymer films of the same material, to achieve the joining by applying a good solvent or a solvent composition for the respective polymer material to one or both films, subsequently pressing the films together and evaporating the solvent. It is, for example, possible to adhesively bond polycarbonate films with methylene chloride. An advantage of using solvent for the joining is that no thermal loading occurs and, specifically in the case of thermoformable polymer materials, the dimensional stability can be improved and collapsing of the voids that are formed can be avoided.

In another refinement of the method, the application of electrodes to the outer surfaces of the two- or multi-layer ferroelectret according to the invention may be performed before and/or after the electrical charging of the inner surfaces of the voids in optional step D). For this purpose, in the two- or multi-layer ferroelectret created according to the invention, the two outwardly directed polymer film surfaces may be continuous surfaces without clearances. The application of electrodes to the outer surfaces is understood in the context of the present invention as meaning the provision of a conductive surface coating in at least a partial region, in particular to the outwardly directed surfaces of the two- or multi-layer ferroelectret according to the invention. The electrodes are arranged with preference on continuous surfaces, that is to say on surfaces without clearances, of the polymer films used.

According to the invention, after the application of electrodes to the outer surfaces of the two- or multi-layer ferroelectret, direct charging can be performed by applying an electric voltage. Before the application of electrodes, a polarization of the opposite sides of the voids may be realized, for example by a corona discharge. A corona treatment can advantageously also be used well on a large scale. According to the invention, it is also possible first to provide a conductive surface coating on one surface, then to charge the two- or multi-layer ferroelectret according to the invention and finally to apply a second electrode to the opposite outer surface.

Therefore, the two- or multi-layer ferroelectrets produced according to the invention may at least partially have a conductive coating on the outwardly directed surfaces of the polymer films. These conductive regions can be used as electrodes. The conductive coating, that is to say the electrodes, may in this embodiment be applied in a two-dimensional and/or structured manner. A structured conductive coating may, for example, be configured as an application in strips or in the form of a grid. As a result, the sensitivity of the two- or multi-layer ferroelectret according to the invention can be additionally influenced and adapted to specific applications.

The selected electrode materials may be conductive materials known to a person skilled in the art. According to the invention, metals, metal alloys, conductive oligomers or polymers, such as for example polythiophenes, polyanilines, polypyrroles, conductive oxides, such as for example mixed oxides such as Indium-tin oxide (ITO), or polymers filled with conductive fillers come into consideration, for example, for this. Metals, conductive carbon-based materials, such as for example carbon black, carbon nanotubes (carbon nanotubes (CNT)) or once again conductive oligomers or polymers, come into consideration, for example, as fillers for polymers filled with conductive fillers. The filler content of the polymers in this case lies above the percolation threshold, so that the conductive fillers form continuous electrically conductive paths.

The electrodes may be realized by methods known to those in the art, for example by a metallization of the surfaces, by sputtering, vapor deposition, chemical vapor deposition (CVD), printing, knife application, spin coating, adhesively attaching or pressing on a conductive layer in a prefabricated form or through a spray electrode from a conductive plastics material. The electrodes may be of a structured configuration, for example in the form of strips or a grid. For example, according to the invention, the electrodes may also be structured in such a way that, as an electromechanical transducer, the two- or multi-layer ferroelectret according to the invention has active and passive regions. In particular, the electrodes may be structured such that, in particular in a sensor mode, the signals can be detected in a locally resolved manner and/or, in particular in an actuator mode, the active regions can be activated in a specific manner. This can be achieved, for example, by the active regions being provided with electrodes, whereas the passive regions have no electrodes.

The invention also includes the possibility of joining two or more two- or multi-layer ferroelectrets with a conductive layer of the same polarity, that is to say an electrode. In other words it is possible to form between two two- or multi-layer ferroelectrets according to the invention an intermediate electrode which can be connected to the two electrodes on the then outer surfaces. As a result, the two- or multi-layer ferroelectrets according to the invention can be connected in series and the achievable piezoelectric effect can be doubled, or multiplied.

Preferably, the two- or multi-layer ferroelectrets according to the invention include two electrodes. Electromechanical transducers according to the invention with more than two electrodes may be stacked constructions (stacks) comprising a number of two- or multi-layer ferroelectrets, preferably produced according to the invention.

In another refinement of the method according to the invention, steps A), B), C) and/or D) may be carried out as a continuous reel-to-reel process. The production of the two- or multi-layer ferroelectrets according to the invention may therefore be advantageously carried out at least partially as a continuous process, preferably as a reel-to-reel process. This is particularly advantageous for the application of the methods on a large, industrial scale. The automation of at least some of the production methods simplifies the methods and makes low-cost production of the two- or multi-layer ferroelectrets according to the invention with voids possible.

According to the invention, all the steps of the method advantageously allow automation.

In another refinement, the sealing of the edges of the two- or multi-layer ferroelectret according to the invention formed in step C) may take place in a further step E) before or after the charging in step D). The two- or multi-layer ferroelectrets according to the invention can consequently be advantageously sealed at the edges, to protect them hermetically from environmental influences, for example in applications in an aggressive environment, for example in atmospheres with high air humidity or under water.

In another embodiment of the method according to the invention, the voids formed may be filled with a gas. The gas may in this case be, for example, pure nitrogen (N₂), nitrogen oxide (N₂O) or sulphur hexafluoride (SF₆). The gas filling advantageously allows even significantly higher piezo constants to be achieved by the polarization in the case of the two- or multi-layer ferroelectrets produced according to the invention.

An immense advantage of the provided methods according to the invention, also in their various refinements described above, is that they are material-independent in wide areas, and as a result there is a broad possibility of applications.

The invention also relates to a two- or multi-layer ferroelectret with voids, with the exception of a three-layer ferroelectret with a perforated middle layer made of PTFE between two FEP layers, containing
at least a first polymer film element with at least one surface side having clearances, and
at least a first covering,

the covering being arranged on the first surface side of the first polymer film clement, having clearances, and

the clearances being closed by the covering while voids are formed.

The two- or multi-layer ferroelectret according to the invention is preferably produced by a method according to the above description.

Here, the various provided variants of the production method and the resultant two- or multi-layer ferroelectrets according to the invention may, if appropriate, also be carried out in combination with one another. Such two- or multi-layer ferroelectrets according to the invention comprise polymer films piled in the form of a stack and voids formed at least between two polymer films. The polymer films are in this case joined to one another between the voids. According to the invention, the form and dimensioning of the voids can be advantageously produced in a very exactly predetermined and defined manner.

In another embodiment of the invention, the polymer film element and/or the covering may, according to the invention, also include at least two polymer films joined to one another. As a result, the variability of the two- or multi-layer ferroelectrets created according to the invention can be increased further. The overall height and the number of voids, or the number of layers with voids, can be established on the basis of the chosen total number of polymer films and the chosen sequence of polymer films in the polymer film element and the covering with and without clearances. In a polymer film element according to the invention, for example, is also possible for two, three or more polymer films to be arranged one above the other, if appropriate also with voids lying in between, and joined to one another. For example, polymer films with clearances and continuous polymer films may be arranged one above the other in an alternating manner in the film stack of the polymer film element. The invention also relates to a piezoelectric element containing a two- or multi-layer ferroelectret according to the invention. This piezoelectric element may, with particular preference, be a sensor, actuator or generator element. The invention can be advantageously realized in a large number of extremely different applications in the electromechanical and electroacoustic area, in particular in the area of energy generation from mechanical oscillations (energy harvesting), acoustics, ultrasound, medical diagnostics, acoustic microscopy, mechanical sensor technology, in particular compression, stress and/or strain sensor technology, robotics and/or communications technology. Examples include pressure sensors, electroacoustic transducers, microphones, loudspeakers, vibration transducers, light deflectors, membranes, modulators for glass fiber optics, pyroelectric detectors, capacitors and control systems and “intelligent” floors. In comparison with piezoceramic devices, the polymer-based two- or multi-layer ferroelectrets according to the invention have the advantage that they are flexible, deformable and not brittle and that they can be produced over a large surface area, i.e. also in the range of square meters. Furthermore, they have the advantage that they can be customized, i.e., for example, the resonant frequency and the mechanical, electrical and piezoelectric properties can be set within wide ranges. Moreover, the methods for producing the two- or multi-layer ferroelectrets according to the invention, for example reel-to-reel methods or extrusion, are less complex than the methods for producing piezoceramics.

In addition, the invention also includes a device for producing two- or multi-layer ferroelectrets according to the invention. In other words, the invention also relates to a device for carrying out the method according to the invention, the device containing means for removing polymer material for the introduction of clearances into at least one surface side of a polymer film element and/or a covering. These means may, for example, be devices such as a milling head, a plane or a laser.

Thus, methods for producing two- or multi-layer ferroelectrets with voids that can be carried out simply and at low cost even on a large scale are provided according to the invention. The two- or multi-layer ferroelectrets created by the methods according to the invention can also be produced with a greater number of layers with an exactly defined void structure. The variable adjustability of the cross-sectional geometry and the dimensioning, form and size of the voids, the layer sequence and number of layers as well as the great selection of materials for the polymer films used allow the two- or multi-layer ferroelectrets created according to the invention to be designed particularly well for corresponding application areas.

The figures described below are intended to explain the invention in further detail without restriction to the embodiments that are shown and described.

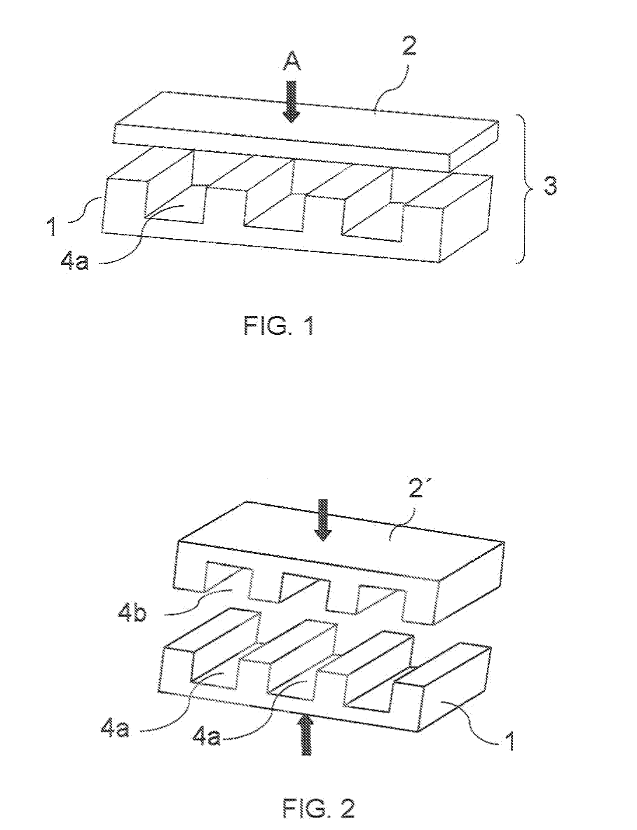

FIG. 1 schematically shows the application according to the invention of a covering 2 to a polymer film clement 1, that is to say in other words substep B) in the production of a two-layer ferroelectret 3 according to the invention. In the embodiment shown, the polymer film element 1 is a polymer film which has clearances 4a in one surface side. The covering 2 is configured as a completely continuous polymer film without clearances 4b and can be arranged on the surface side of the polymer film 1 in which the clearances 4a are formed according to the invention by removal of polymer material. The polymer film element 1 and the covering 2 may be of the same configuration in their base area and arranged one above the other in such a way that they finish flush with one another. In the embodiment represented, the clearances 4a and voids 5 formed from them with the covering 2 may have a rectangular cross section perpendicularly and parallel to the run of the layers of the polymer film element 1 and of the covering 2. The voids 5 within the polymer film composite 3 formed may advantageously make the two-layer ferroelectret according to the invention that is to be produced softer along its thickness, that is to say perpendicularly to the run of the layers of the polymer film element 1 and of the covering 2, in order to lower its modulus of elasticity and make a polarization process possible in the resultant voids. The joining of the two polymer films 1 and 2 may, for example, be performed according to the invention by laminating, adhesive bonding, clasping, clamping, screwing, riveting or welding.

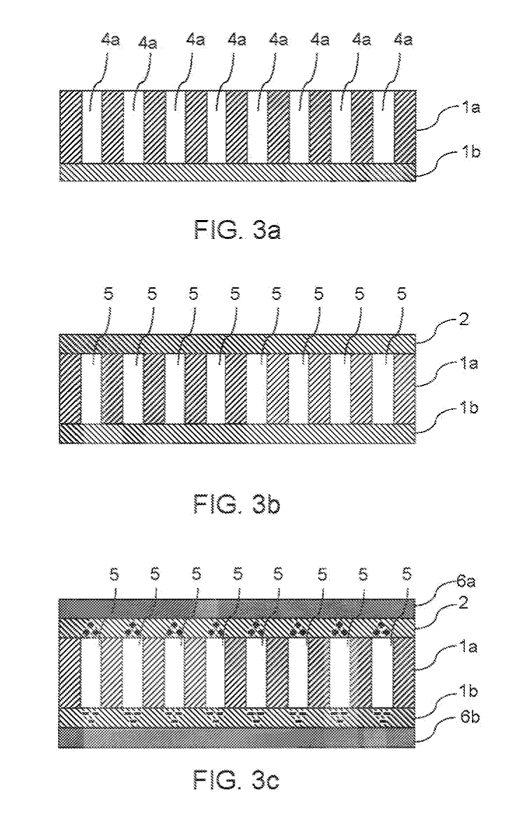

Like FIG. 1, FIG. 2 shows substep B) of the method according to the invention for producing a two-layer ferroelectret 3. In the embodiment shown, the polymer film element 1 is likewise a polymer film which has clearances 4a in one surface side. In the configuration according to invention that is shown, the covering 2 is likewise provided on one surface side with clearances 4b. The clearances 4a and 4b may in each case be introduced according to the invention into the surface sides of the polymer films by methods of removal such as laser ablation, etching, planing, milling or grinding. The clearances 4a, 4b may be created according to the invention in forms, sizes and distributions that are the same or not the same. In the embodiment shown, the covering 2 and the polymer film element 1 are of a congruent configuration with regard to their surface sides directed towards one another with the clearances 4a and 4b, so that the clearances 4a and 4b arranged one above the other in the two-layer ferroelectret according to the invention 3 created respectively form a common void 5. The height of the voids 5 can in this case be advantageously significantly greater with the same polymer film thicknesses than when a continuous covering without clearances is used. By the choice of a covering 2 that likewise has clearances 4b, the height of the voids created then be advantageously selected over a very much greater range and, if appropriate, be adapted to specific applications.

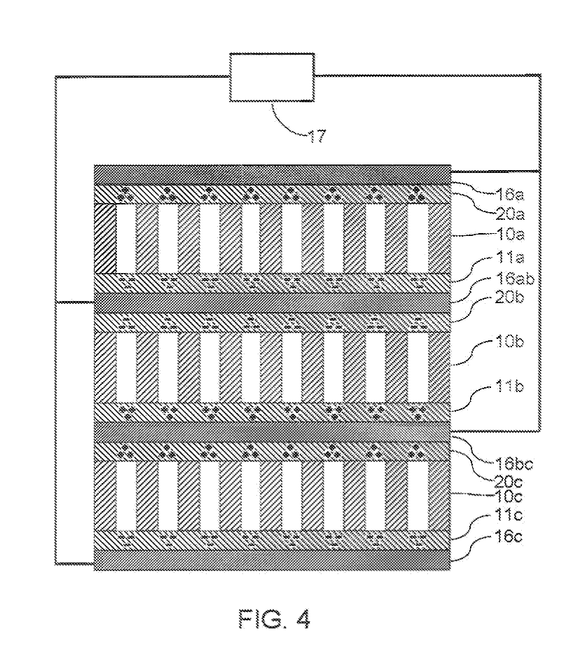

FIG. 3a shows a sectional view of a polymer film element 1 which can be formed from a composite of two polymer films la and lb. The joining of the two polymer films la and lb may be performed, for example, by laminating or adhesive bonding. According to the invention, clearances 4a may then be introduced into the polymer film la by means of methods of removal, such as laser ablation, etching, milling, planing or grinding. In the polymer film element 1 shown, the clearances 4a have been introduced into the polymer film la right through as far as the second polymer film lb. The removal of the polymer material as far as the bounding surface of the polymer films la and lb advantageously allows the heights of the voids to be set more exactly, and even more uniform voids can be created as a result.

FIG. 3b shows a sectional representation of a three-layer ferroelectret 3 according to the invention comprising the polymer film element 1 shown in FIG. 3a and a continuous covering 2. The clearances 4a are closed by the covering 2 while a layer of voids 5 is formed. A layer of voids is understood according to the invention as meaning and referring to such a layer that can be formed in the same polymer film layer. The voids within the three-layer ferroelectret according to the invention formed may advantageously make the three-layer ferroelectret according to the invention that is to be produced softer along its thickness, that is to say perpendicularly to the run of the layers of the polymer films 1a, 1b, 2, in order to lower its modulus of elasticity and make a polarization process possible in the resultant voids 5.

FIG. 3c is a schematic sectional view through the three-layer ferroelectret according to the invention shown in FIG. 3b after the charging process and after the attachment of electrodes 6a and 6b. The charging may be performed, for example, by tribo charging, electron beam bombardment, application of an electric voltage to the electrodes or corona discharge. In particular, the charging may be performed through a two-electrode corona arrangement. In this case, the needle voltage may be at least ≧20 kV, for example at least ≧25 kV, in particular at least ≧30 kV. The charging time may in this case be at least >0 s, for example at least ≧30 s, in particular at least ≧1 min. The continuous polymer film lb and the covering 2 in each case contact an electrode 6a, 6b. The electrodes 6a, 6b arc formed here as electrode layers, in each case on the sides of the polymer film 1b and of the covering 2 that are arranged opposite the sides to which the polymer film la forming voids 5, comprising clearances, is adjacent.

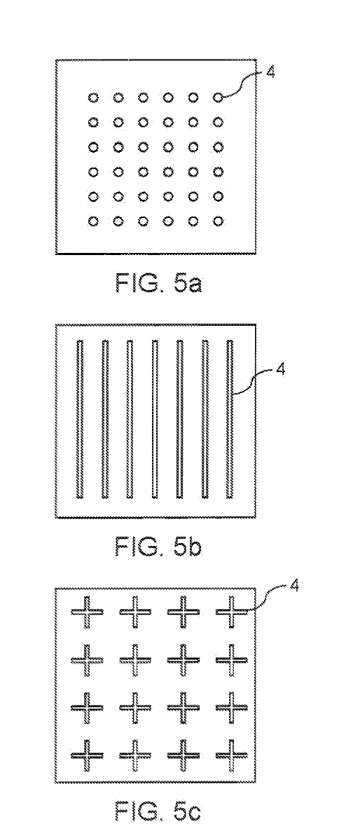

FIG. 4 shows a schematic cross section through an electromechanical transducer according to the invention with three multi-layer ferroelectrets according to the invention stacked one above the other, as represented in FIG. 3c, which in each case contain a continuous polymer film 11a, 11b, 11c, a polymer film 10a, 10b, 10c having clearances, which in each case together form the polymer film element 1, and a covering in the form of a third continuous polymer film 20a, 20b. 20c. FIG. 4 illustrates that two adjacent continuous polymer films 11a, 20b; 11b, 20c of the different arrangements are charged with a polarization that is the same and can thereby contact the same electrode 16ab; 16bc. FIG. 4 additionally shows a possibility for connecting the electrodes 16a, 16ab, 16bc, 16c to a voltage/current-measuring/supplying/storing device 17.

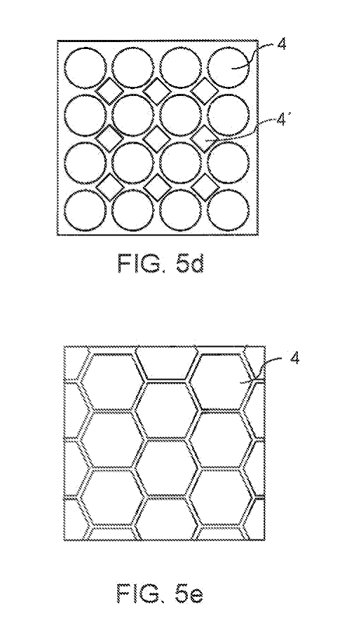

FIGS. 5a-5e show schematic plan views of various embodiments of clearances 4 in the polymer film elements 1 and/or coverings 2, and consequently the possible configuration of the base areas of the corresponding voids 5 transversely to the run of the layers of the polymer films 1 and/or 2. The structures shown may also be created by methods of removal, for example by laser ablation, milling, planing or grinding and/or chemically by etching. In principle, it is possible to carry out the removal in such a way that the forms can be created as positive or negative forms, that is to say as depressions or elevations, in the polymer films 1 and 2. The embodiments and configurations of the clearances 4 that are shown only represent examples and are not intended to restrict the invention in any form. For reasons of overall clarity, only one clearance of a form is respectively identified by a reference sign by way of example in FIGS. 5a to 5e.

FIG. 5a shows a plan view of a polymer film 1 having clearances 4, the clearances 4 having a circular base area. As illustrated in FIG. 5a, the clearances 4 may additionally be formed as a multiplicity of clearances 4.

FIG. 5b shows a plan view of a polymer film 1 having clearances 4, the clearances 4 having an elongated, rectangular base area.

FIG. 5c shows a plan view of a polymer film having clearances 4, the clearances 4 of which have a cruciform base area.

FIG. 5d shows a structured polymer film having various clearances 4, 4′, some of the clearances of which have a circular base area 4 and some have a rhomboidal base area 4′. FIG. 5d illustrates that, with a homogeneously distributed arrangement of clearances with circular 4 and rhomboidal 4′ cross-sectional areas, a particularly great overall void volume can be advantageously achieved.

FIG. 5e shows a polymer film 1 having clearances 4, the depressions 4 of which have a honeycomb-shaped base area. FIG. 5e illustrates that an arrangement that is based exclusively on clearances 4 with honeycomb-shaped cross-sectional areas likewise allows an advantageously great overall void volume to be achieved.

What is claimed is:

1. A method for producing a two- or multi-layer ferroelectret with voids, said method comprising:
A) introducing one or more clearances into at least one surface side of a polymer film element by means of a method of removal,
B) applying a first covering to the surface side of the polymer film element comprising clearances formed in step A), and
C) joining the polymer film element and the covering to form a polymer film composite, the clearances being closed while voids are formed
with the proviso that with the two- or multi-layer ferroelectret excludes three-layer ferroelectrets with a perforated middle layer made of PTFE between two FFP layers.

2. The method according to claim 1, wherein the introduction of the clearances in step A) is performed by one or more selected from the group consisting of laser ablation, etching, planing, grinding and milling.

3. The method according to claim 1, wherein one or more clearances are introduced into a surface side of the covering in a further step A1).

4. The method according to claim 3, wherein the clearances in the surface side of the covering and the clearances in the surface side of the polymer film element arc arranged such that they at least partially overlap, and consequently form a common void.

5. The method according to claim 1, wherein the polymer film clement and/or the covering comprise at least a first and a second polymer film joined to one another.

6. The method according to claim 5, wherein the introduction of the clearances into the surface side of the polymer film element in step A) and/or the introduction of the clearances into the surface side of the covering in a further step A1) is performed through as far as the second polymer film.

7. The method according to claim 1, wherein the joining of the polymer film element and the covering to form a two- or multi-layer ferroelectret in step C) is performed by one selected from the group consisting of laminating, adhesive bonding, clasping, clamping, screwing, riveting or welding.

8. The method according to claim 1, wherein the application of electrodes to the outwardly directed surfaces of the two- or multi-layer ferroelectret is performed before and/or after the electrical charging of the inner surfaces of the voids in a further step D).

9. The method according to claim 1, wherein steps A), B), C) and/or 13) are carried out as a continuous reel-to-reel process.

10. The method according to claim 1, wherein the method further comprises sealing of edges of the two- or multi-layer ferroelectret formed in step C) as a further step E) before or after electrical charging of the inner surfaces of the voids in an additional step D).

11. The method according to claim 1, wherein the method further includes filling voids in the two- or multi-layer ferroelectret (3) with gas in a further step F) before the polarization in an additional step D).

12. A two- or multi-layer ferroelectret with voids comprising
at least a first polymer film element with at least one surface side comprising clearances, and
at least a first covering,
the covering being arranged on a first surface side of the polymer film element, comprising clearances, and
the clearances being closed by the covering while voids are formed, with the proviso that with the two- or multi-layer ferroelectret excludes three-layer ferroelectrets with a perforated middle layer made of PTFE between two FEP layers.

13. A two- or multi-layer ferroelectret produced by the method according to claim 1.

14. A piezoelectric element containing a two- or multi-layer ferroelectret produced according to claim 12 wherein the polymer film element and/or the covering comprise at least two polymer films joined to one another.

15. The piezoelectric element according to claim 14, wherein the element comprises a sensor, actuator and/or generator element.

16. A piezoelectric element containing a two- or multi-layer ferroelectret produced according to claim 13, wherein the polymer film element and/or the covering comprise at least two polymer films joined to one another.

17. The piezoelectric element according to claim 16, wherein the element comprises a sensor, actuator and/or generator element.
